(19) United States
(12) Patent Application Publication
(10) Pub. No.: US 2016/0192525 A1
(43) Pub. Date: Jun. 30, 2016

(54) STACKED PACKAGE STRUCTURE

(71) Applicant: PHOENIX PIONEER TECHNOLOGY CO., LTD., Hsinchu County (TW)

(72) Inventors: Chu-Chin Hu, Hsinchu County (TW); Chin-Ming Liu, Hsinchu County (TW)

(21) Appl. No.: 14/964,733

(22) Filed: Dec. 10, 2015

(30) Foreign Application Priority Data
Dec. 26, 2014 (CN) 201410826347.1

(51) Int. Cl. H05K 7/02; H01L 25/065; H05K 7/06

(52) U.S. Cl. CPC H05K 7/023; H05K 7/06; H01L 25/0657; H01L 25/0652; H01L 2225/06572

(57) ABSTRACT

A stacked package structure is provided. The stacked package structure includes a first substrate, a first electronic component disposed on and electrically connected to the first substrate, and a second substrate disposed on the first substrate and covering the first electronic component, the second substrate having an opening corresponding in position to the first electronic component. Therefore, the first electronic component is prevented from colliding with the second substrate to cause displacement, such that loss of yield is reduced.

### BACKGROUND OF THE INVENTION

1. Field of the Invention

The present invention relates to packages, and, more particularly, to a stacked package structure.

2. Description of Related Art

As the semiconductor packaging technology continues to advance, various types of packages of a semiconductor device have been developed to increase electrical functionality and reduce packaging space. For instance, a package on package (PoP) is developed by having multiple packaging structures stacked on one another. This type of package has the property of heterogeneous integration of a System in Package (SiP), and is capable of incorporating and integrating various electronic components of different functions, such as memory, central processing unit, graphic processor, image processor, etc., in a package through stacking, such that it is very suitable to be used in various low-profile electronic products.

Early stacked package structures are formed by stacking one package over another package via solder balls only. Later on, a type of stacked package structure is developed with the use of copper pillars acting as supporting structures to electrically connect the upper and lower packages.

FIG. 1 illustrates a cross-sectional schematic view of a conventional stacked package structure 1.

As shown in FIG. 1, a first substrate 10 having opposing first and second surfaces 10, 10b is formed, a plurality of copper pillars 140 are formed on the first surface 10a of the first substrate 10, an electronic component 11 is formed on and electrically connected to the first surface 10a first substrate 10, a second substrate 12 is formed on the copper pillars 140, and then an encapsulant 19 is formed between the first surface 10a of the first substrate 10 and the second substrate 12. Specifically, the second substrate 12 is coupled with the copper pillars 140 via a plurality of metal pillars 141 and solder materials 142, and together the copper pillars 140, metal pillars 141 and solder materials 142 form the conductive elements 14.

However, in the conventional stacked package structure 1, the electronic component 11 is disposed between the first substrate 10 and second substrate 12, such that the electronic component 11 could be easily displaced by colliding with the second substrate 12, leading to a loss of yield. Further, if the conductive elements 14 increase in height in order to avoid being collided with the second substrate 12 or causing damages to the electronic component 11, the overall height of the stacked package structure 1 increases too. As such, the demand for low-profiling cannot be met.

Thus, there is an urgent need for solving the problems of the prior art.

### SUMMARY OF THE INVENTION

In view of the foregoing drawbacks, the present invention provides a stacked package structure, which includes a first substrate having opposing first and second surfaces; at least one first electronic component disposed on the first surface of the first substrate and electrically connected with the first substrate; and a second substrate disposed on the first surface of the first substrate and covering the first electronic component, wherein the second substrate has at least one opening, to which at least one first electronic component corresponds in position.

In summary, the stacked package structure of the present invention involves using a second substrate having openings, to allow the first electronic component to correspond in position to the opening, and thereby preventing the first electronic component from being collided with the second substrate to cause displacement. As a result, loss of yield can be reduced.

Further, since the first electronic component corresponds in position to the opening, the height of the second substrate can be reduced, without damaging the first electronic component. As such, the overall height of the stacked package structure can be reduced for meeting the low-profile requirement.

In addition, the design of the opening makes alignment easy, and thereby simplifying the fabricating process.

### BRIEF DESCRIPTION OF THE DRAWINGS

FIG. 1 is cross-sectional schematic view showing a conventional stacked package structure;

FIGS. 2A to 2C are cross-sectional schematic views showing a stacked package structure in accordance with a first embodiment of the present invention;

FIG. 2A′ is a cross-sectional schematic view showing a stacked package structure in accordance with another embodiment of FIG. 2A;

FIGS. 3A to 3C are cross-sectional schematic views showing stacked package structures in accordance with a second embodiment of the present invention;

FIGS. 3A′ to 3C′ are cross-sectional structure views showing stacked package structures in accordance with another embodiment of FIGS. 3A-3C; and

FIG. 4 is a cross-sectional view showing a stacked package structure in accordance with a fourth embodiment of the present invention.

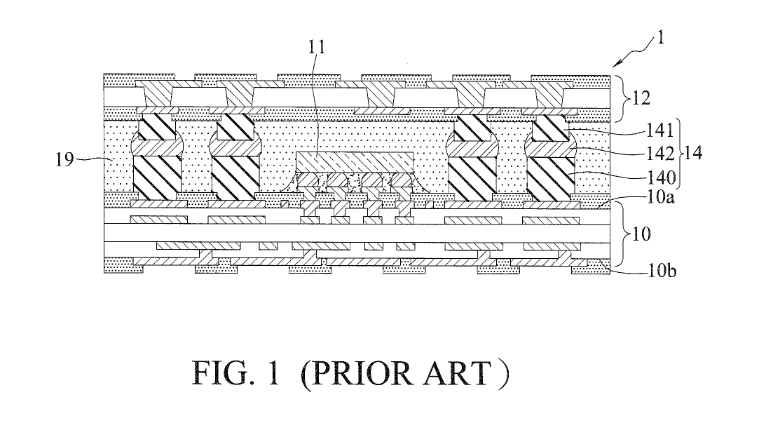

### DETAILED DESCRIPTION OF THE PREFERRED EMBODIMENTS

The present invention is described in the following with specific embodiments, so that one skilled in the art can easily understand other advantages and effects of the present invention from the disclosure of the present specification.

It should be noted that the structures, proportions, sizes, etc. illustrated in the figures appended to the present specification are all merely used for coping with the content of disclosure of the present specification, so as to enhance the understanding and perusal of one skilled in the art. They are not used to limit the implemental limitations of the present invention, such that they lack substantial technical meanings. Without affecting the effect brought about and the goals to be achieved by the present invention, any modification of a structure, alteration of a proportion or adjustment of a size should still fall within the scope of the technical content disclosed in the present invention. At the same time, terms, such as “above,” “below,” “top,” “first,” “second,” “one,” etc. used in the present specification, are merely for the clarity of the descriptions, rather than limit the implemental scope of the present invention. Without substantially altering the technical content, an alteration or adjustment of relative positioning can also be regarded as an implemental scope of the present invention.

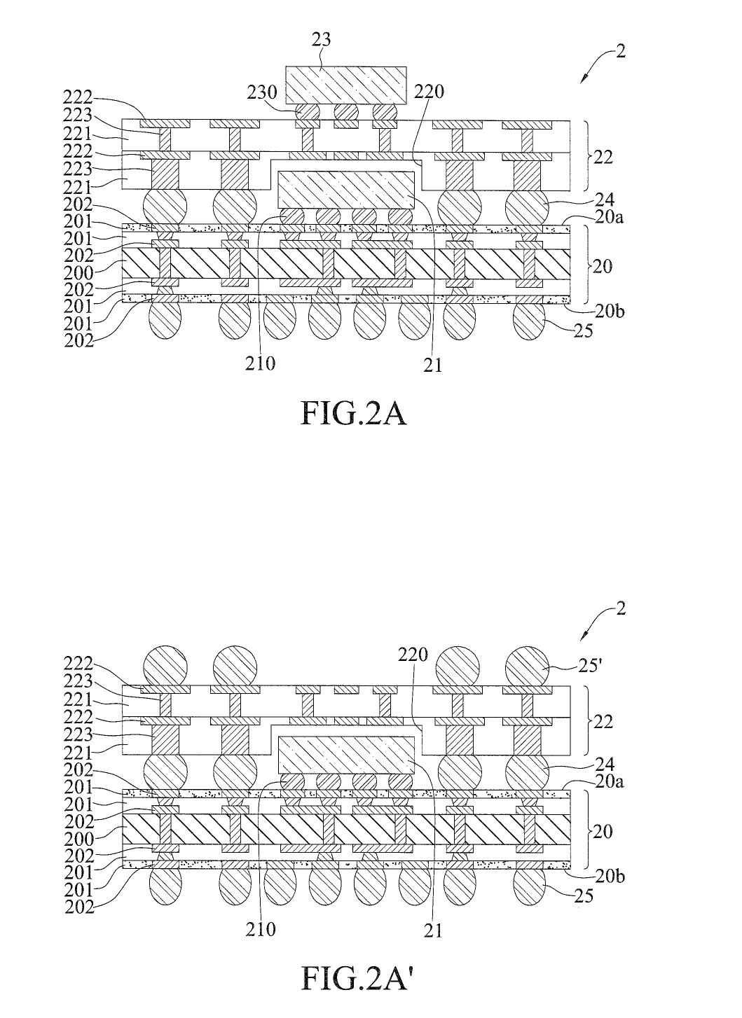

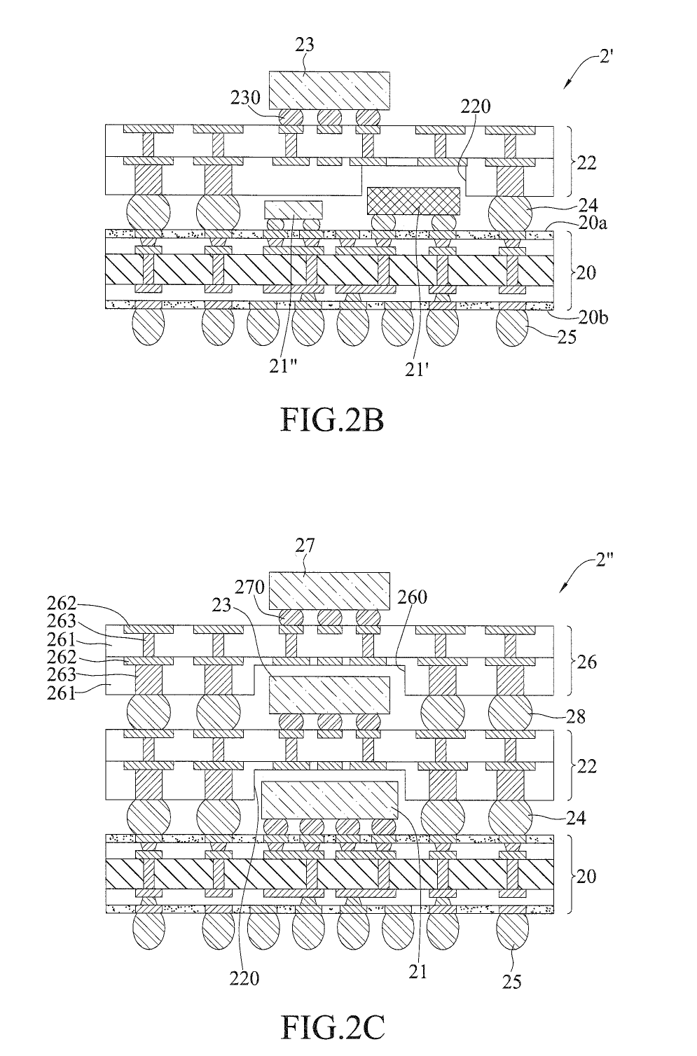

FIGS. 2A to 2C are cross-sectional schematic views showing a stacked package structure in accordance with a first embodiment of the present invention.

As shown in FIG. 2A, a stacked package structure 2 includes a first substrate 20, a first electronic component 21, and a second substrate 22.

The first substrate 20 has a first surface 20a and a second surface 20b opposing the first surface 20a.

In an embodiment, the first substrate 20 is a circuit board having a core layer 200. Specifically, the first substrate 20 includes a core layer 200, a plurality of insulating layers 201 disposed on the top and bottom sides of the core layer 200, and a wiring layer 202 embedded in each of the insulating layers 201, wherein the surfaces of the outermost insulating layer 201 serve as the first surface 20a and second surface 20b of the first substrate, allowing the outermost wiring layers 202 to be exposed from the first surface 20a and the second surface 20b of the first substrate.

Further, a plurality of solder balls 25 are formed on the outermost wiring layers 202 under the first substrate 20, for mounting an electronic device, such as printed circuit, board (not shown).

The first electronic component 21 is disposed on the first surface 20a of the first substrate 20, and electrically connected with the first substrate 20, wherein the electrical connection can be achieved via wire bonding or a conductive layer.

In an embodiment, the first electronic component 21 is an active component, passive component or a combination thereof. The active component can be, for example, a semiconductor element (such as chip), while the passive component can be, for example, a resistor, a capacitor or an inductor, wherein the first electronic component 21 shown in FIG. 2A is an active component.

Further, the first electronic component 21 is mounted on and electrically connected with the wiring layer 202 via printing or dispensing a conductive material 210 (such as a solder material or conductive adhesive), wherein the electrical connection can be achieved via wire bonding.

The second substrate 22 is disposed on the first surface 20a of the first substrate 20, and covers the first electronic component 21, i.e., the first electronic component 21 is positioned between the first substrate 20 and the second substrate 22. Further, the second substrate 22 has an opening 220, such that the first electronic component 21 corresponds in position to the opening 220. For instance, the first electronic component 21 is received in the opening 220 without contacting the second substrate 22.

In an embodiment, the second substrate 22 is a circuit board having a coreless layer. Specifically, the second substrate 22 includes a plurality of insulating layer 221, a wiring layer 222 embedded in each of the insulating layers 221, and a plurality of conductive bodies 223 (such as copper pillars) disposed in the insulating layer 221 and electrically connected with the wiring layer 222, wherein one of the insulating layers 221 (i.e., the bottom insulating layer 221) has the opening 220, for exposing a portion of the wiring layer 222 (i.e., the bottom wiring layer 222) from the opening 220.

Further, on the side having the opening 220, the terminal surfaces of the conductive bodies 223 (i.e., bottom conductive bodies 223) are exposed from the insulating layers 221, such that a plurality of the conductive elements 24, such as solder balls, are formed on the terminal surfaces of the conductive bodies 223, allowing the conductive elements 24 to be coupled with the outermost wiring layers 202 on the top of the first substrate 20, such that the second substrate 22 is stacked on the first surface 20a of the first substrate 20 via the conductive elements 24.

Further, the opening 220 can be formed by molding, laser burning, and milling, pumice grinding, or chemical etching.

The stacked package structure 2 further includes a second electronic component 23 disposed on the insulating layer 221 on top of the second substrate 22, and electrically connected with the second substrate 22.

In an embodiment, the second electronic component 23 is an active component, passive component or a combination thereof, and the active component can be, for example, a semiconductor element (such as a chip), while the passive component can be, for example, a resistor, a capacitor or an inductor, wherein the second electronic component 23 shown in FIG. 2A is an active component.

Further, the second electronic component 23 is mounted on and electrically connected with the wiring layer 222 above by printing or dispensing a conductive material 210 (such as solder material or conductive adhesive).

In addition, as shown in FIG. 2A′, the disposition of the second electronic component 23 can be omitted. Instead, a plurality of solder balls 25 are formed on the wiring layer 222′, for an electronic device (not shown), such as a printed circuit board, to be mounted thereon.

As shown in FIG. 2B, a stacked package structure 2′ can also have a plurality of first electronic components 21′, 21″, wherein one of the first electronic component 21″ can be an active component, while the other first electronic component 21′ may be a passive component, such as in a multi-layer ceramic capacitor (MLCC).

Further, as shown in FIG. 2B, the first electronic component 21″ may not correspond in position to the opening 220, and the first electronic component 21″ does not contact the second substrate 22.

As shown in FIG. 2C, a stacked package structure 2″ may further include a third substrate 26 and a third electronic component 27.

The third substrate 26 is disposed on the second substrate 22 and covers the second electronic component 23.

In an embodiment, the third substrate 26 is a circuit board having a coreless layer. Specifically, the third substrate 26 can be structurally the same as the second substrate 22, allowing the second electronic component 23 to be received in an opening 260 of the third substrate 26.

Further, the third substrate 26 is formed on the side having the opening 260, and the bottom conductive bodies 263 of the third substrate 26 have the terminal surfaces being exposed from the bottom insulating layer 261 of the third substrate 26, allowing a plurality of conductive elements 28, such as solder balls, to be formed on the terminals surfaces of the conductive bodies 263, such that the third substrate 26 is stacked over the second substrate 22 via the conductive elements 28.

The third electronic component 27 is disposed on and electrically connected with the third substrate 26.

In an embodiment, the third electronic component 27 is an active component, a passive component or a combination thereof. The active component is, for example, a semiconductor element (such as a chip), and the passive component is, for example, a resistor, a capacitor or an inductor. The third electronic component 27 shown in FIG. 2C is an active component.

Further, the third electronic component 27 is mounted on and electrically connected with a wiring layer 262 via printing or dispensing a conductive material 270 (such as solder material or conductive adhesive).

In the stacked package structures of 2, 2′, 2″ of the present invention, a second substrate 22 or a third substrate 26 having openings 220, 260, respectively, are used to allow the first electronic components 21, 21′ or the second electronic component 23 to correspond in position to the openings 220, 260, and thereby avoiding the first electronic components 21, 21′ or the second electronic component 23 from colliding with the second substrate 22 or the third substrate 26 to cause displacement. As a result, loss of yield can be reduced, and thereby simplifying the fabrication process.

Further, since the first electronic components 21, 21′ or the second electronic component 23 correspond in position to the openings 220, 260, respectively, the heights of the conductive elements 24, 28 can be reduced. As such, the overall height of the stacked package structures 2, 2′, 2″can be reduced, for meeting the low-profile requirement.

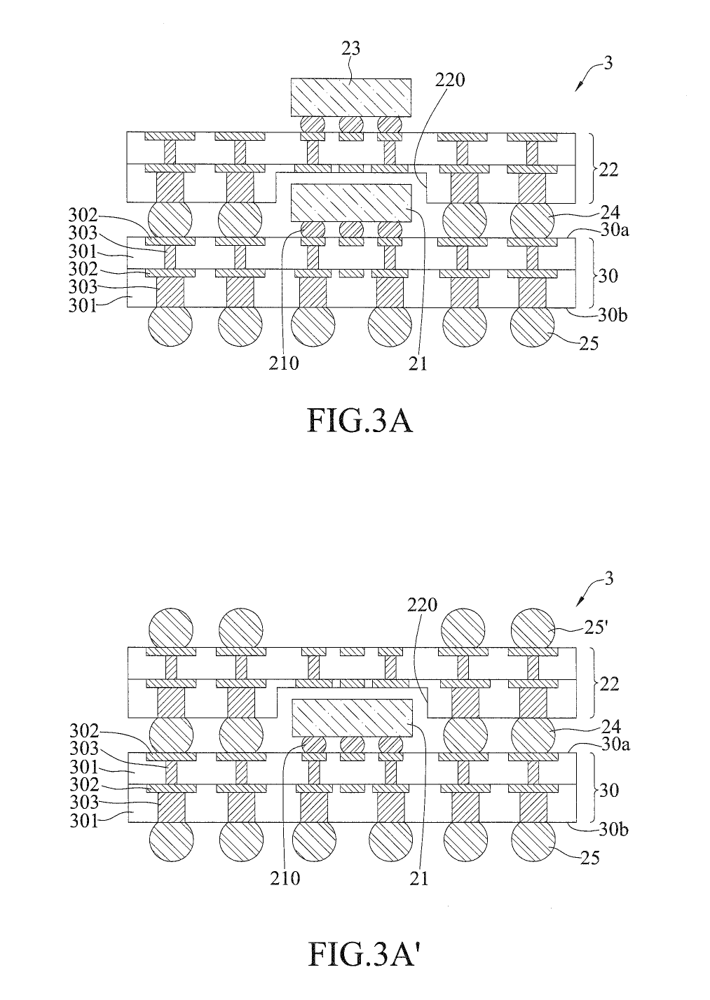

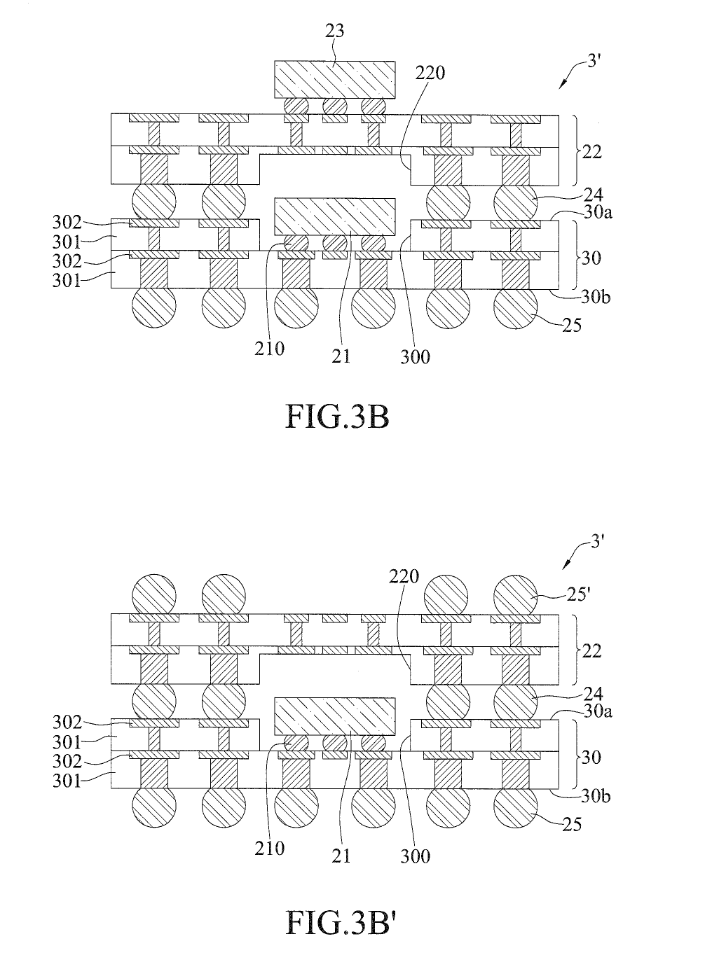

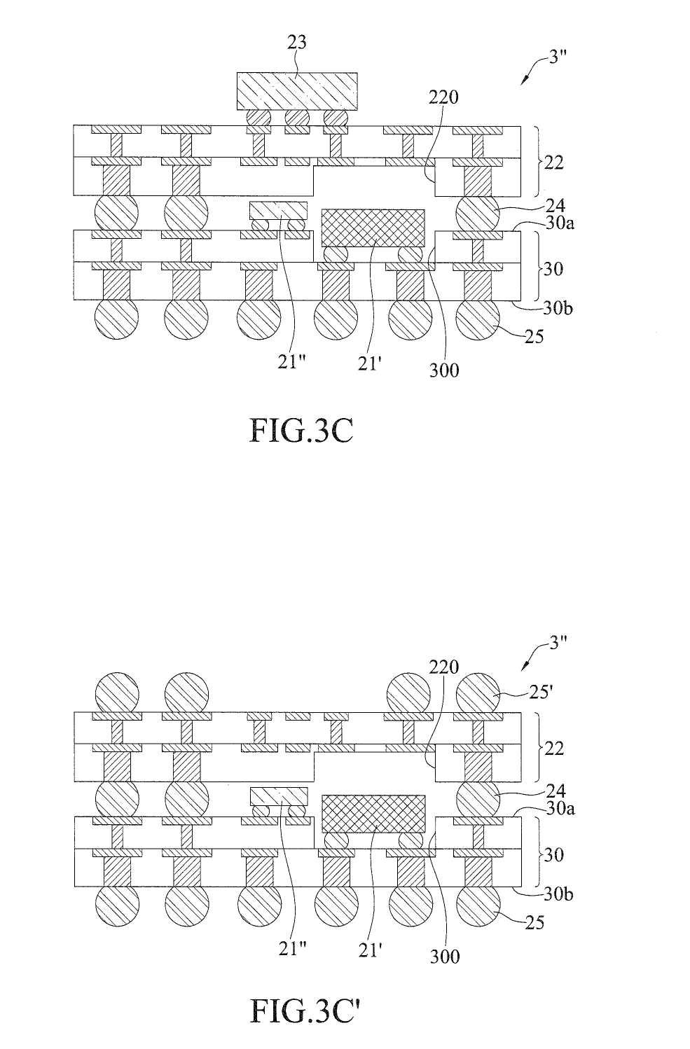

FIGS. 3A to 3C are cross-sectional schematic views showing stacked package structures in accordance with a second embodiment of the present invention. FIGS. 3A′ to 3C′ are variations of the example according to FIG. 2A′. This embodiment differs from the first embodiment in the structure of the first substrate, while the rest of other structures are the same. Therefore, only the difference will be described hereinafter.

As shown in FIGS. 3A and 3A′, a first substrate 30 is a circuit board having a coreless layer. Specifically, the first substrate 30 is structurally similar to the second substrate 22, but the first substrate 30 does not have an opening.

In an embodiment, the surfaces of outermost insulating layer 301 serve as a first surface 30a and a second surface 30b. The terminal surfaces of the bottom conductive bodies 303 of the first substrate 30 are exposed from the second surface 30b, for forming a plurality of solder balls 25 on the terminal surfaces of the conductive bodies 303 for another electronic device (not shown), such as a printed circuit board, to be mounted thereon.

Further, the first electronic component 21 is mounted on and electrically connected with a wiring layer 302 on the first substrate 30 via printing or dispensing the conductive material 210 (such as solder material or conductive adhesive).

Moreover, the conductive elements 24 are mounted on the top wiring layer 302 on the first substrate 30, for the second substrate 22 to be stacked on a first surface 30a of the first substrate 30 via the conductive elements 24.

In addition, as shown in the stacked package structures 3′ shown in FIGS. 3B and 3B′, the first substrate 30 may have a recessed portion 300, for the first electronic component 21 to be received therein. Specifically, the recessed portion 300 is formed on one of the insulating layers 301 (i.e., the top insulating layer 301), and the recessed portion 300 is at the position corresponding to the opening 220, allowing a portion of the wiring layer 302 (i.e., the bottom wiring layer 302) to be exposed from the recessed portion 300, such that the first electronic component 21 is mounted on and electrically with bottom wiring layer 302 via the conductive material 210.

Alternatively, as shown in FIGS. 3C and 3C′, the stacked package structure 3″ may have a plurality of first electronic components 21, 21′, and one of the first electronic components 21′ is received in the recessed portion 300, while the other first electronic component 21 is not received in the recessed portion 300 and the opening 220. However, the first electronic components 21, 21′ do not contact the second substrate 22.

In the stacked package structures 3′, 3″ according to the present invention, a recessed portion 300 is formed in the first substrate 30, for the first electronic components 21, 21′ to be received therein, and thereby avoiding the first electronic components 21, 21′ from colliding with the second substrate 22 to cause displacement. Thus, loss of yield is reduced. The overall height of the conductive elements 24 and the stacked package structures 3′, 3″ are reduced, for meeting the low-profile requirement.

Further, the design of the opening 220 or recessed portion 300 also makes alignment easy, and thereby simplifying the fabricating process.

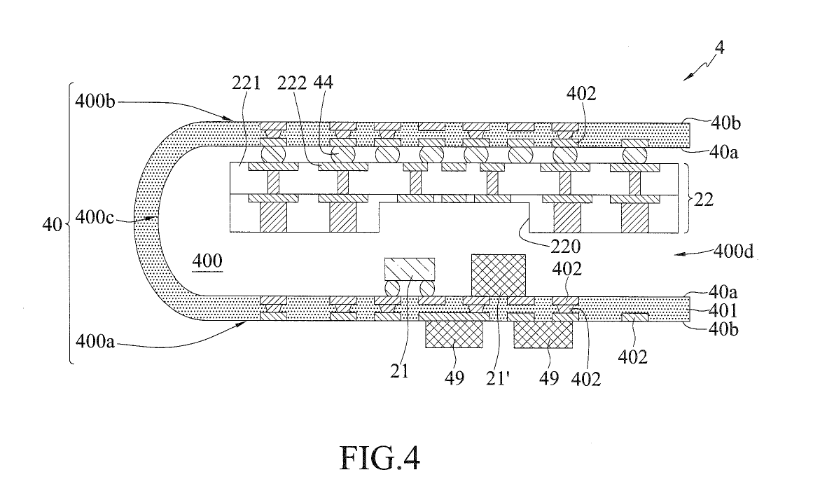

FIG. 4 is a cross-sectional schematic view showing a stacked package structure in accordance with a fourth embodiment of the present invention. This embodiment differs from the first embodiment in the structure of the first substrate, while the rest of other structures are the same. Therefore, only the difference will be described hereinafter.

As shown in FIG. 4, a stacked package structure 4 has a plurality of first electronic components 21, 21′, and a first substrate 40 may be a flexible substrate, which can be bent to form into a U shape. The first substrate 40 is bent to form with an accommodating space 400, such that the first substrate 40 is divided into opposing first and second portions 400a, 400b, and a connecting portion 400c interconnecting the first portion 400a and second portion 400b, and a gap 400d is formed between the first portion 400a and the second portion 400b. The first electronic components 21, 21′ are formed on the first surface 40a of the first portion 400a. In other words, the first electronic components 21, 21′ are disposed in the accommodating space 400.

In an embodiment, the first substrate 40 includes an insulating layer 401, and a plurality of wiring layers 402 embedded in the insulating layer 401. The surfaces of the insulating layer 401 serve as a first surface 40a and a second surface 40b, allowing the wiring layer 402 to be exposed from the first surface 40a and second surface 40b and the first surface 40a of the first portion 400a to be disposed by facing the first surface 40a of the second portion 400b.

Further, the second substrate 22 is disposed on the first surface 40a of the second portion 400b and covers the first electronic components 21, 21′. The second substrate 22 has the opening 220, allowing the first electronic components 21, 21′ to correspond in position to the opening 220.

Further, on the side of the second substrate 22 without forming the opening 220, the wiring layer 222 (i.e., the top wiring layer 222) is exposed from the insulating layer 221, for forming a plurality of conductive elements 44, such as solder balls, on the exposed surface of the wiring layer 222, allowing the conductive elements 44 to be coupled to the wiring layer 402 on the second portion 400b of the first substrate 40, such that the second substrate 22 is stacked on the first surface 40a of the first substrate 40 via the conductive elements 44.

In addition, the stacked package structure 4 further includes a plurality of fourth electronic components 49 disposed on the second surface 40b of the first portion 400a of the first substrate 40, and electrically connected with the wiring layer 402 on the first portion 400a of the first substrate 40.

The fourth electronic components 49 are each is an active component, a passive component or a combination thereof. The active component can be, for example, a semiconductor element (such as a chip). The passive component can be, for example, a resistor, a capacitor or a inductor. The fourth electronic components 49 described in FIG. 4 are passive components.

In the stacked package structure 4 of the present invention, the first electronic components 21, 21′ correspond in position to the opening 220, and thereby avoiding the first electronic components 21, 21′ from colliding with the second substrate 22 to cause displacement. As a result, loss of yield can be reduced. The height of the connecting portion 400c can also be reduced (i.e., through further bending the first substrate 40), and thereby reducing the overall height of the stacked package structure 4 for meeting the low-profile requirement.

Further, the design of the opening 220 makes alignment easy, thereby simplifying the fabricating process.

In summary, the stacked package structure of the present invention involves the use of a second substrate having an opening to allow the first electronic component to correspond in position to the opening, and thereby avoiding the first electronic component from colliding with the second substrate to cause displacement. As a result, loss of yield can be reduced. Further, the design of the opening also makes alignment easy, and thereby simplifying the fabricating process.

Further, since the first electronic component corresponds in position to the opening, the height of the second substrate can be reduced, without damaging the first electronic component. As such, the overall height of the stacked package structure can be reduced for meeting the low-profile requirement.

The principles and effects of the present invention have been described using the above examples, which are not used to limit the present invention. Without departing from the spirit and scope of the present invention, any one skilled in the art can modify the above examples. Therefore, the scope of the present invention should be accorded with the claims appended.

What is claimed is:

1. A stacked package structure, comprising:
a first substrate having opposing first and second surfaces;
at least one first electronic component disposed on the first surface of the first substrate and electrically connected with the first substrate; and
a second substrate disposed on the first surface of the first substrate and covering the first electronic component, wherein the second substrate has at least one opening, to which the at least one first electronic component corresponds in position.

2. The stacked package structure of claim 1, wherein the first substrate is a circuit board having a core layer.

3. The stacked package structure of claim 1, wherein the second substrate is a circuit board without a core layer.

4. The stacked package structure of claim 1, further comprising at least one second electronic component formed on and electrically connected with the second substrate.

5. The stacked package structure of claim 1, further comprising a third substrate disposed on the second substrate.

6. The stacked package structure of claim 5, further comprising at least one third electronic component formed on and electrically connected with the third substrate.

7. The stacked package structure of claim 1, wherein the first substrate is a circuit board without a core layer.

8. The stacked package structure of claim 1, wherein the first substrate has a recessed portion for receiving the at least one first electronic component.

9. The stacked package structure of claim 1, wherein the first substrate is a flexible substrate so as to be bent to form an accommodating space such that the flexible substrate is divided into a first portion, an opposing second portion, and a connecting portion interconnecting the first and second portions in a manner that the first electronic component is formed on the first portion, and the second substrate is formed on the second portion.

10. The stacked package structure of claim 1, further comprising at least one fourth electronic component disposed on the second surface of the first substrate, and electrically connected with the first substrate.
